(19) United States
(12) Patent Application Publication
(10) Pub. No.: US 2026/0066016 A1
(43) Pub. Date: Mar. 5, 2026

(54) EFUSE MEMORY

(71) Applicant: Shanghai Huali Integrated Circuit Corporation, Shanghai (CN)

(72) Inventors: Yujuan GUO, Shanghai (CN); Lingling ZHAO, Shanghai (CN); Ying YAN, Shanghai (CN)

(73) Assignee: Shanghai Huali Integrated Circuit Corporation, Shanghai (CN)

(21) Appl. No.: 19/190,076

(22) Filed: Apr. 25, 2025

(30) Foreign Application Priority Data
Aug. 30, 2024 (CN) 202411215927.7

(51) Int. Cl. G11C 17/16; G11C 17/18; H10B 20/25

(52) U.S. Cl. CPC G11C 17/16; G11C 17/18; H10B 20/25

(57) ABSTRACT

The present disclosure provides an efuse memory, where an efuse cell structure includes a control transistor composed of a MOS transistor and a link structure. The MOS transistor is formed in a first active area. The link structure is formed in a second active area parallel to the first active area. The link structure includes first and second link connection areas, and an active area link located between the first and second link connection areas. The first link connection area is connected to a drain line of the MOS transistor. The second link connection area is connected to a bit line. The active area link includes on and off states.

### CROSS-REFERENCES TO RELATED APPLICATIONS

This application claims priority to Chinese patent application No. CN202411215927.7, filed on Aug. 30, 2024, the disclosure of which is incorporated herein by reference in its entirety.

### TECHNICAL FIELD

The present disclosure relates to a semiconductor integrated circuit, and in particular to an electronic fuse (efuse) memory.

### BACKGROUND

An efuse cell generally consists of one link and one control transistor composed of a MOS transistor. It achieves an on-chip programming function with high reliability by fusing the link based on the principle of electromigration (EM). A chip area, which is one of main indicators of efuse, is mainly determined by an array of efuse cells. Therefore, a method of improving a layout of the efuse cell becomes an important way to reduce an overall area of efuse.

An existing layout of the conventional efuse cell includes one link and one NMOS control transistor. A link material is typically polysilicon or metal. FIG. 1 is a diagram of an array layout of an existing efuse memory, where layouts 102 of a plurality of efuse cell structures are arranged in the array layout 101.

FIG. 2 illustrates a layout 102 of the efuse cell structure in FIG. 1. It can be seen from FIG. 2 that the efuse cell structure includes one MOS transistor 103 and one link 104. The MOS transistor 103 is typically an NMOS transistor and is located in an NMOS area. The link 104 is located in a link area.

In FIG. 2, the dashed line in the link area illustrates a structure of the link 104. The link 104 includes pads formed by two metal layers and a metal line connected between the two pads. During programming, a voltage is applied between the two pads to fuse the metal line by means of EM.

In the existing efuse cell structure shown in FIG. 2, the area of the MOS transistor 103 occupies most of the entire cell area and is a main area in the efuse cell layout, and the MOS transistor 103 is a core factor that determines the overall area of efuse.

Dimensions of the efuse cell are also shown in FIG. 2, which correspond to dimensions of an efuse cell formed by a 28 HK process, i.e., 28 nm high dielectric constant (HK) process, where an area of 14.4 square micrometers is obtained by multiplying a length with a width.

### BRIEF SUMMARY

According to some embodiments in this application, an efuse memory disclosed in this application includes an efuse cell structure.

The efuse cell structure includes a control transistor composed of a MOS transistor and a link structure.

The MOS transistor is formed in a first active area (AA).

The link structure is formed in a second active area, and the first active area is parallel to the second active area.

The link structure includes a first link connection area, an active area link, and a second link connection area.

The active area link is located between the first link connection area and the second link connection area.

The top of the first link connection area is connected to a drain line of the MOS transistor through a contact (CT).

The top of the second link connection area is connected to a bit line through the contact.

The active area link includes on and off states.

When the efuse cell structure is in an initial state, the active area link is in the on state, and the drain and the bit line are electrically connected together.

When the efuse cell structure is in a programmed state, the active area link is in a fused state, and the drain and the bit line are electrically disconnected from each other.

In some cases, the MOS transistor includes a gate structure, a source area, and a drain area.

The gate structure is stripe-shaped and parallel to the stripe-shaped second active area.

The source area and the drain area are formed in the first active area on two sides of the gate structure in a self-aligned manner.

The drain area is connected to the drain line of the MOS transistor through the contact.

In some cases, the first active area and the second active area are connected together through a third active area.

A first side of the third active area is connected to the drain area adjacent thereto and formed in the first active area.

A second side of the third active area is connected to one of the first link connection area and the second link connection area.

The top of the third active area is also connected to the drain line through the contact.

In some cases, the drain area extends to the third active area or the drain area and extends to the third active area and the first link connection area or the second link connection area adjacent to the third active area. A constituent part of the active area link includes a metal silicide formed on the surface of the second active area.

In some cases, the source area is connected to a source line through the contact.

The gate structure is connected to the word line through the contact.

In some cases, the gate structure includes a gate dielectric layer and a gate conductive material layer stacked in sequence.

In some cases, the material of the gate dielectric layer includes a high dielectric constant material; and the material of the gate conductive material layer includes polysilicon or metal.

In some cases, the MOS transistor is formed by a plurality of MOS transistor units connected in parallel.

The gate structures of all the MOS transistor units are arranged in parallel.

The source area located between two gate structures is shared by two MOS transistor units.

The drain area located between two gate structures is shared by two MOS transistor units.

In some cases, two efuse cell structures form one efuse cell pair.

In a top view, the two efuse cell structures are centrally symmetrical.

In some cases, the efuse cell structure further includes a fourth active area, and the fourth active area serves as an active area dummy structure.

The fourth active area and the second active area are parallel and spaced apart, and the first active area and the fourth active area are located on two sides of the second active area.

In some cases, in the efuse cell pair, the two efuse cell structures share one fourth active area.

In some cases, the two efuse cell structures of the efuse cell pair are a first efuse cell structure and a second efuse cell structure, respectively.

The two efuse cell structures share the same bit line.

Each gate structure of the first efuse cell structure is connected to a first word line through the corresponding contact.

Each gate structure of the second efuse cell structure is connected to a second word line through the corresponding contact.

Each source area of the first efuse cell structure is connected to a first source line.

Each source area of the second efuse cell structure is connected to a second source line.

Each drain area of the first efuse cell structure is connected to a first drain line.

Each drain area of the second efuse cell structure is connected to a second drain line.

In a top view, the first word line is perpendicular to the bit line.

The first word line, the second word line, the first source line, and the first drain line are parallel, and the first source line and the first drain line are located between the first word line and the second word line.

The first source line and the second drain line are located on the same straight line and spaced apart.

The first drain line and the second source line are located on the same straight line and spaced apart.

In some cases, each word line, each source line, and each drain line are composed of a second metal layer that is patterned.

The bit line is composed of a third metal layer that is patterned.

In some cases, each efuse cell structure has three electrode ports for connection to an external circuit, a source port, which is a source port, a word line port, and a bit line port, respectively.

The word line is connected to the corresponding the word line port, the source line is connected to the corresponding source port, and the bit line is connected to the corresponding bit line port.

In some cases, the efuse array structure is formed by the efuse cell pairs arranged repeatedly.

In some cases, the MOS transistor includes more than three MOS transistor units.

In some cases, the MOS transistor is an NMOS transistor.

Unlike the prior art in which the link structure of the efuse cell structure is disposed in the metal layer, the link structure of the present disclosure is disposed in an active area layer, the programming is achieved by fusing the active area link, and the link structure having the active area link may be achieved just by adding the second active area adjacent and parallel to the first active area of the MOS transistor, greatly reducing the area of the link structure of the present disclosure relative to the area of the link structure in the metal layer of the prior art, thereby reducing cell dimensions, i.e., reducing the area of the efuse cell structure.

The link structure of the present disclosure facilitates a combined layout of the efuse cell structures, for example, two efuse cell structures can form a centrally symmetric efuse cell pair, and then the efuse array is formed by arranging the efuse cell pairs, reducing a free area in an array structure, thus reducing a layout area of an array, and thereby improving the layout area utilization and the layout work efficiency.

### BRIEF DESCRIPTION OF THE DRAWINGS

The present disclosure is further described in detail below with reference to the drawings and specific embodiments:

FIG. 1 is a diagram of an array layout of an existing efuse memory;

FIG. 2 illustrates a layout of an efuse cell structure in FIG. 1;

FIG. 3 illustrates a layout of an efuse cell structure of an efuse memory according to an embodiment of the present disclosure;

FIG. 4 is a circuit diagram of the efuse cell structure in FIG. 3;

FIG. 5 illustrates a layout of an efuse cell pair of an efuse memory according to an embodiment of the present disclosure;

FIG. 6 illustrates a layout with a metal layer superimposed thereon based on FIG. 5; and

FIG. 7 is a circuit diagram of the efuse cell pair of an efuse memory according to an embodiment of the present disclosure.

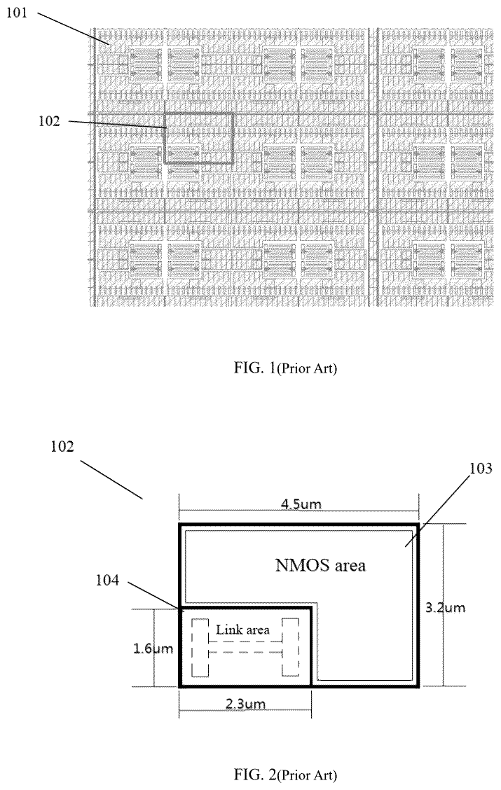

### DETAILED DESCRIPTION OF THE DISCLOSURE

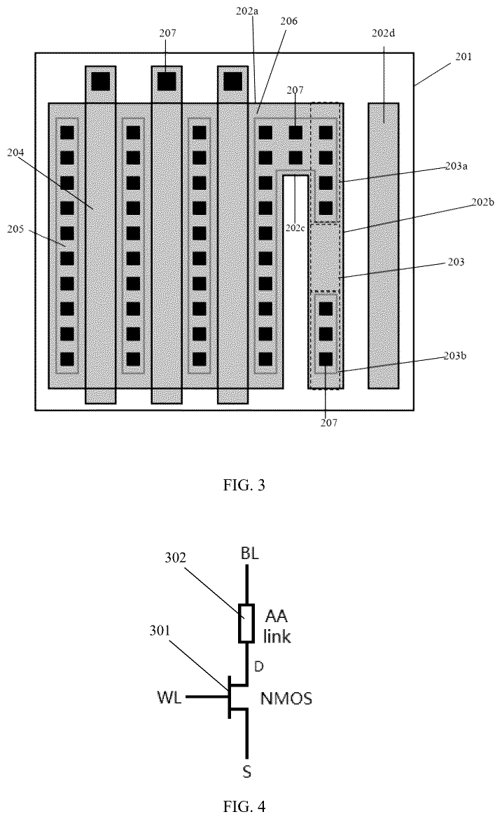

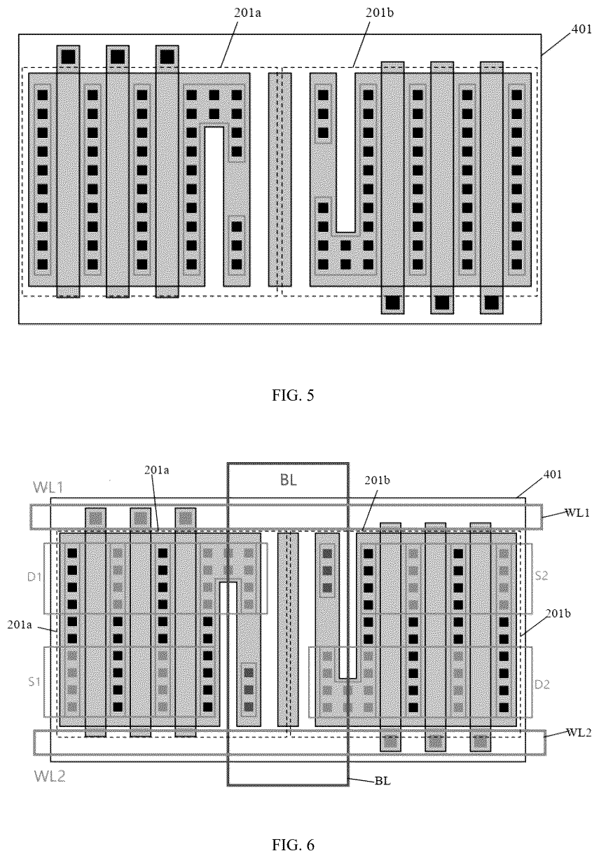

FIG. 3 illustrates a layout of an efuse cell structure 201 of an efuse memory according to an embodiment of the present disclosure. FIG. 4 is a circuit diagram of the efuse cell structure 201 in FIG. 3. The efuse memory of this embodiment of the present disclosure includes the efuse cell structure 201.

Referring to FIG. 4, the efuse cell structure 201 includes a control transistor composed of a MOS transistor 301 and a link structure 302.

Referring to FIG. 3, the MOS transistor 301 is formed in a first active area 202a.

The link structure 302 is formed in a second active area 202b, and the first active area 202a is parallel to the second active area 202b.

The link structure 302 includes a first link connection area 203a, an active area link 203, and a second link connection area 203b.

The active area link 203 is located between the first link connection area 203a and the second link connection area 203b.

The top of the first link connection area 203a is connected to a drain line D of the MOS transistor 301 through a contact 207. The drain line D of the MOS transistor 301 may be referred to FIG. 4.

The top of the second link connection area 203b is connected to a bit line BL through the contact 207. The bit line BL may be referred to FIG. 4.

The active area link 203 includes on and off states.

When the efuse cell structure 201 is in an initial state, the active area link 203 is in the on state, and the drain and the bit line BL are electrically connected together.

When the efuse cell structure 201 is in a programmed state, the active area link 203 is in a fused state, and the drain and the bit line BL are electrically disconnected from each other.

Referring to FIG. 3, the MOS transistor 301 includes a gate structure 204, a source area 205, and a drain area 206.

The gate structure 204 is stripe-shaped and parallel to the stripe-shaped second active area 202b.

The source area 205 and the drain area 206 are formed in the first active area 202a on two sides of the gate structure 204 in a self-aligned manner.

The drain area 206 is connected to the drain line D of the MOS transistor 301 through the contact 207.

In this embodiment of the present disclosure, the first active area 202a and the second active area 202b are connected together through a third active area 202c.

A first side of the third active area 202c is connected to the drain area 206 adjacent thereto and formed in the first active area 202a.

A second side of the third active area 202c is connected to one of the first link connection area 203a and the second link connection area 203b. FIG. 3 shows that the second side of the third active area 202c is connected to the first link connection area 203a.

In the field of semiconductor integrated circuit manufacturing, an active area is composed of a semiconductor substrate in an area enclosed by a field oxide such as a shallow trench isolation (STI) that is formed in the semiconductor substrate. It can be seen from FIG. 3 that the first active area 202a, the second active area 202b, and the third active area 202c are connected together to present an integral structure.

The top of the third active area 202c is also connected to the drain line D through the contact 207.

In this embodiment of the present disclosure, the source area 205 is connected to a source line S through the contact 207.

The gate structure 204 is connected to the word line WL through the contact 207.

The gate structure 204 includes a gate dielectric layer and a gate conductive material layer stacked in sequence.

In some embodiments, the material of the gate dielectric layer includes a high dielectric constant material; the material of the gate conductive material layer is metal; and the gate structure 204 is HKMG. In other embodiments, the material of the gate dielectric layer may be silicon dioxide, and the material of the gate conductive material layer may be polycrystalline silicon.

Referring to FIG. 3, in this embodiment of the present disclosure, the MOS transistor 301 is formed by a plurality of MOS transistor units connected in parallel.

The gate structures 204 of all the MOS transistor units are arranged in parallel.

The source area 205 located between two gate structures 204 is shared by two MOS transistor units.

The drain area 206 located between two gate structures 204 is shared by two MOS transistor units.

In some embodiments, the MOS transistor 301 includes more than three MOS transistor units.

FIG. 3 shows three gate structures 204, and therefore the MOS transistor 301 includes three MOS transistor units. An area covered by the gate structure 204 serves as a channel area of the corresponding MOS transistor unit. In FIG. 3, three gate structures 204 divide the first active area 202a outside the area covered by the gate structure 204 into four areas, that is, there are two source areas 205 and two drain areas 206. In FIG. 3, from left to right, the source area 205, the drain area 206, the source area 205, and the drain area 206 are formed in the four areas of the first active area 202a outside the area covered by the gate structure 204, respectively. The rightmost drain area 206 is in contact with the first side of the third active area 202c.

In some embodiments, the MOS transistor 301 is NMOS. The source area 205 and the drain area 206 are both N+ doped. In other embodiments, the MOS transistor 301 may be PMOS.

In FIG. 4, the MOS transistor 301 is also denoted by NMOS, and the link structure 302 is also denoted by AA link.

In some embodiments, the drain area 206 extends to the third active area 202c or the drain area 206 and extends to the third active area 202c and the first link connection area 203a or the second link connection area 203b adjacent to the third active area 202c.

In this embodiment of the present disclosure, a constituent part of the active area link 203 includes a metal silicide formed on the surface of the second active area 202b. In some embodiments, the metal silicide forming the active area link 203 includes NiSi, where the metal silicide may be fused by means of electromigration, thereby implementing fusing programming of the active area link 203. The second active area 202b at the bottom of the metal silicide in the active area link 203 then serves as a link dielectric.

In some embodiments, the metal silicide is also formed on the surface of each source area 205 and each drain area 206.

In this embodiment of the present disclosure, the efuse cell structure 201 further includes a fourth active area 202d, and the fourth active area 202d serves as an active area dummy structure.

The fourth active area 202d and the second active area 202b are parallel and spaced apart, and the first active area 202a and the fourth active area 202d are located on two sides of the second active area 202b.

In this embodiment of the present disclosure, each efuse cell structure 201 has three electrode ports for connection to an external circuit, which are a source port, a word line port, and a bit line port, respectively.

The word line is connected to the corresponding the word line port, the source line is connected to the corresponding source port, and the bit line is connected to the corresponding bit line port.

The drain line does not directly form a port connected to the outside; and if the active area link 204 is in the on state, the drain line may be connected to the bit line port.

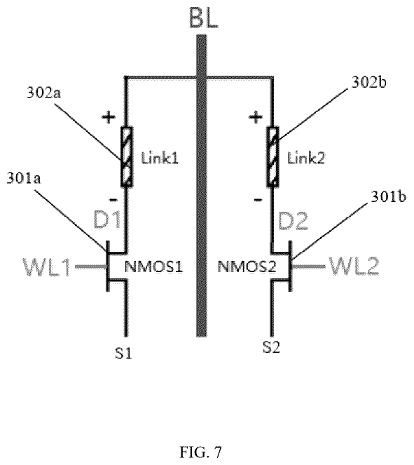

FIG. 5 illustrates a layout of an efuse cell pair 401 of an efuse memory according to an embodiment of the present disclosure. FIG. 6 illustrates a layout with a metal layer superimposed thereon based on FIG. 5. FIG. 7 is a circuit diagram of the efuse cell pair 401 of an efuse memory according to an embodiment of the present disclosure. In this embodiment of the present disclosure, two efuse cell structures 201 form one efuse cell pair 401.

Two efuse cell structures 201 form one efuse cell pair 401. In FIG. 5, the two efuse cell structures 201 of the efuse cell pair 401 are a first efuse cell structure 201a and a second efuse cell structure 201b, respectively.

In a top view, the two efuse cell structures 201 are centrally symmetrical.

In the efuse cell pair 401, the two efuse cell structures 201 share one fourth active area 202d.

Referring to FIG. 6, the two efuse cell structures 201 share the same bit line BL.

Each gate structure 204 of the first efuse cell structure 201a is connected to a first word line WL1 through the corresponding contact 207.

Each gate structure 204 of the second efuse cell structure 201b is connected to a second word line WL2 through the corresponding contact 207.

Each source area 205 of the first efuse cell structure 201a is connected to a first source line S1.

Each source area 205 of the second efuse cell structure 201b is connected to a second source line S2.

Each drain area 206 of the first efuse cell structure 201a is connected to a first drain line D1.

Each drain area 206 of the second efuse cell structure 201b is connected to a second drain line D2.

In a top view, the first word line WL1 is perpendicular to the bit line BL.

The first word line WL1, the second word line WL2, the first source line S1, and the first drain line D1 are parallel, and the first source line S1 and the first drain line D1 are located between the first word line WL1 and the second word line WL2.

The first source line S1 and the second drain line D2 are located on the same straight line and spaced apart.

The first drain line D1 and the second source line S2 are located on the same straight line and spaced apart.

Each word line WL, each source line S, and each drain line D are composed of a second metal layer (M2) that is patterned.

The bit line BL is composed of a third metal layer (M3) that is patterned.

In FIG. 7, the first MOS transistor 301a of the first efuse cell structure 201a is denoted by NMOS1.

The first drain line is denoted by D1.

The first source line is denoted by S1.

The first word line is denoted by WL1.

The first link structure 302a is denoted by Link1.

The second MOS transistor 301b of the second efuse cell structure 201b is denoted by NMOS2.

The second drain line is denoted by D2.

The second source line is denoted by S2.

The second word line is denoted by WL2.

The second link structure 302b is denoted by Link2.

In this embodiment of the present disclosure, the efuse array structure is formed by the efuse cell pairs 401 arranged repeatedly.

Unlike the prior art in which a link structure of an efuse cell structure is disposed in the metal layer, the link structure 302 of this embodiment of the present disclosure is disposed in an active area layer, the programming is achieved by fusing the active area link 203, and the link structure 302 having the active area link 203 may be achieved just by adding the second active area 202b adjacent and parallel to the first active area 202a of the MOS transistor 301, greatly reducing the area of the link structure 302 of this embodiment of the present disclosure relative to the area of the link structure 302 in the metal layer of the prior art, thereby reducing cell dimensions, i.e., reducing the area of the efuse cell structure 201.

The link structure 302 of this embodiment of the present disclosure facilitates a combined layout of the efuse cell structures 201, for example, two efuse cell structures 201 can form a centrally symmetric efuse cell pair 401, and then the efuse array is formed by arranging the efuse cell pairs 401, reducing a free area in an array structure, thus reducing a layout area of an array, and thereby improving the layout area utilization and the layout work efficiency.

It can be seen from the above that in this embodiment of the present disclosure, the AA layer is used as a link dielectric composed of one NMOS transistor and one AA layer link, and the efuse cell is a three-port (WL, BL, S) device. The efuse cell is composed of one AA layer link (AA-link) and one NMOS transistor. A gate end of the NMOS transistor forms the port WL. The NMOS transistor is located on a side of the AA layer link, where the AA layer and the AA layer link at a drain end thereof are disposed in parallel and connected to an end of the link, and a connection between the AA layer and the M1 layer is formed by the CT at a position where they are connected. AA dummy is disposed on the other side of the AA layer link, and the AA dummy serves as a protection line. The other end of the AA layer link is connected to the M1 layer through three CTs to form the port BL. In the efuse cell pair 401, the two efuse cells are in a top-bottom inverted layout and share the same BL port. An efuse storage array area is formed by combining the efuse cells, i.e., by splicing layouts of individual cells.

In this embodiment of the present disclosure, the AA layer is used as a link dielectric, and the AA link and the AA of the MOS transistor are integrated together, that is, the AA layer link and the AA layer at the drain end of the MOS transistor are directly connected together, reducing the area of the efuse cell, facilitating the reduction of a free area in the efuse cell array, and improving the work efficiency of the efuse layout.

Compared with the existing conventional efuse cell, in the layout of this embodiment of the present disclosure, the AA dielectric link and the AA portion of the NMOS transistor are combined together, not only reducing the area of the efuse cell, but also facilitating a direct combination of the layouts, thereby greatly improving the layout work efficiency and effectively saving the free area in the array layout. The area of the existing efuse cell (the NMOS transistor and link) shown in FIG. 2 is 14.4 μm2. By designing the efuse layout of this embodiment of the present disclosure, the actual area of the efuse cell may be reduced to 11% of the original area corresponding to the existing efuse cell.

The present disclosure is described in detail above through specific embodiments, which, however, do not impose limitations to the present disclosure. Without departing from the principle of the present disclosure, a person skilled in the art may also made many other deformations and improvements, which should also be considered as the scope of protection of the present disclosure.

What is claimed is:

1. An efuse memory, comprising an efuse cell structure, wherein
the efuse cell structure comprises a control transistor composed of a MOS transistor and a link structure;
the MOS transistor is formed in a first active area;
the link structure is formed in a second active area, and the first active area is parallel to the second active area;
the link structure comprises a first link connection area, an active area link, and a second link connection area;
the active area link is located between the first link connection area and the second link connection area;
the top of the first link connection area is connected to a drain line of the MOS transistor through a contact;
the top of the second link connection area is connected to a bit line through the contact;
the active area link comprises on and off states;
when the efuse cell structure is in an initial state, the active area link is in the on state, and the drain and the bit line are electrically connected together; and
when the efuse cell structure is in a programmed state, the active area link is in a fused state, and the drain and the bit line are electrically disconnected from each other.

2. The efuse memory according to claim 1, wherein the MOS transistor comprises a gate structure, a source area, and a drain area;
the gate structure is stripe-shaped and parallel to the stripe-shaped second active area;
the source area and the drain area are formed in the first active area on two sides of the gate structure in a self-aligned manner; and
the drain area is connected to the drain line of the MOS transistor through the contact.

3. The efuse memory according to claim 2, wherein the first active area and the second active area are connected together through a third active area;
a first side of the third active area is connected to the drain area adjacent thereto and formed in the first active area;
a second side of the third active area is connected to one of the first link connection area and the second link connection area; and
the top of the third active area is also connected to the drain line through the contact.

4. The efuse memory according to claim 3, wherein the drain area extends to the third active area or the drain area and extends to the third active area and the first link connection area or the second link connection area adjacent to the third active area; and
a constituent part of the active area link comprises a metal silicide formed on the surface of the second active area.

5. The efuse memory according to claim 3, wherein the source area is connected to a source line through the contact;
the gate structure is connected to the word line through the contact.

6. The efuse memory according to claim 5, wherein the gate structure comprises a gate dielectric layer and a gate conductive material layer.

7. The efuse memory according to claim 6, wherein the material of the gate dielectric layer comprises a high dielectric constant material; and the material of the gate conductive material layer comprises polysilicon or metal.

8. The efuse memory according to claim 7, wherein the MOS transistor is formed by a plurality of MOS transistor units connected in parallel;
the gate structures of all the MOS transistor units are arranged in parallel;
the source area located between two gate structures is shared by two MOS transistor units; and
the drain area located between two gate structures is shared by two MOS transistor units.

9. The efuse memory according to claim 8, wherein two efuse cell structures form one efuse cell pair; and
in a top view, the two efuse cell structures are centrally symmetrical.

10. The efuse memory according to claim 9, wherein the efuse cell structure further comprises a fourth active area, and the fourth active area serves as an active area dummy structure; and
the fourth active area and the second active area are parallel and spaced apart, and the first active area and the fourth active area are located on two sides of the second active area.

11. The efuse memory according to claim 10, wherein in the efuse cell pair, the two efuse cell structures share one fourth active area.

12. The efuse memory according to claim 9, wherein the two efuse cell structures of the efuse cell pair are a first efuse cell structure and a second efuse cell structure, respectively; the two efuse cell structures share the same bit line;
each gate structure of the first efuse cell structure is connected to a first word line through the corresponding contact;
each gate structure of the second efuse cell structure is connected to a second word line through the corresponding contact;
each source area of the first efuse cell structure is connected to a first source line;
each source area of the second efuse cell structure is connected to a second source line;
each drain area of the first efuse cell structure is connected to a first drain line;
each drain area of the second efuse cell structure is connected to a second drain line;
in a top view, the first word line is perpendicular to the bit line;
the first word line, the second word line, the first source line, and the first drain line are parallel, and the first source line and the first drain line are located between the first word line and the second word line;
the first source line and the second drain line are located on the same straight line and spaced apart; and
the first drain line and the second source line are located on the same straight line and spaced apart.

13. The efuse memory according to claim 12, wherein each word line, each source line, and each drain line are composed of a second metal layer that is patterned; and
the bit line is composed of a third metal layer that is patterned.

14. The efuse memory according to claim 12, wherein each efuse cell structure has three electrode ports for connection to an external circuit, which are a source port, a word line port, and a bit line port, respectively; and
the word line is connected to the corresponding the word line port, the source line is connected to the corresponding source port, and the bit line is connected to the corresponding bit line port.

15. The efuse memory according to claim 12, wherein the efuse array structure is formed by the efuse cell pairs arranged repeatedly.
